(19) United States
(12) Patent Application Publication
(10) Pub. No.: US 2014/0009217 A1
(43) Pub. Date: Jan. 9, 2014

(54) CAPACITIVE TOUCH-CONTROL PANEL APPARATUS

(71) Applicant: ILI TECHNOLOGY CORP., Hsinchu County (TW)

(72) Inventors: MING-CHUNG CHANG, HSINCHU CITY (TW); JIM HSU, HSINCHU COUNTY (TW)

(73) Assignee: ILI TECHNOLOGY CORP., HSINCHU COUNTY (TW)

(21) Appl. No.: 13/747,540

(22) Filed: Jan. 23, 2013

(30) Foreign Application Priority Data
Jul. 6, 2012 (CN) 201210235776.2

(51) Int. Cl. H03K 17/96

(52) U.S. Cl. CPC H03K 17/9622
USPC 327/517

(57) ABSTRACT

A capacitive touch-control panel apparatus is illustrated. The capacitive touch-control panel apparatus includes a touch-control substrate and a hub circuit. The touch-control substrate has M touch areas, and each touch-control area includes an axial body and N electrodes. N electrodes are disposed corresponding to the axial body and are electrically connected to the hub circuit. One of the electrodes on each touch-control area is connected to one of the electrodes on the other touch-control area by one-to-one manner, wherein M and N are positive integer.

### BACKGROUND

1. Technical Field

The present disclosure relates to a touch-control panel; in particular, to a capacitive touch-control panel apparatus.

2. Description of Related Art

With the advancement of the technology, the electronic information product is not only progressing toward a direction of being lighter and thinner, but also provides a more friendly human-machine interface so as to bring the convenience for the user. The human-machine interface includes an output interface and an input interface and the human-machine interface acts as a bridge between the user and electronic information product. The liquid crystal panel possesses some advantages, such as slim and light, such that it is easy for user to carry the liquid crystal panel, and the liquid crystal panel gradually replaces the cathode ray tube (CRT) commonly used for traditional output interface. With the use of liquid crystal panel, the input interface of traditional human-machine interface, such as a mouse and a keyboard, is replaced with a touch-control panel.

The capacitive touch-control panel is widely applied in the electronic information product due to the advantage of positioning precisely. The capacitive touch-control panel includes a plurality of sensing units arranged in array manner and the sensing chip electrically connected to the sensing units, wherein the sensing chip is used for sensing a touched state of the capacitive touch-control panel. A plurality of detecting signal lines are connected to each row or each column of the sensing units, and each of the plurality of detecting signal lines is connected to one end of each sensing unit located on each row or each column. When a finger touches any sensing unit, the touched sensing unit may generate a potential variation due to the effect of field coupling, and the sensing chip may acquire at least a touched location on the touch-control panel through detecting variation amounts of detecting signals transmitted by the detecting signal lines.

Because size of liquid crystal screen is getting larger, a resolution of the capacitive touch-control panel thus increases correspondingly, such that more accurate positioning is provided. In other words, for the liquid crystal screen with large size, the capacitive touch-control panel should have a larger sensing unit array, and it means that a large amount of the detecting signal lines should be utilized in the capacitive touch-control panel to transmit the sensing signals outputted by the sensing units. In related art, the sensing chip is electrically connected to each row or each column of sensing unit array of liquid crystal panel through a flexible printed circuit (FPC) board, and the large amount of the detecting signal lines may represent a fact that it needs the sensing chip with more pins and the FPC with larger area. However, it may increase cost of the sensing chip and FPC and increase difficulty for circuit layout on the capacitive touch-control panel. Therefore, the capacitive touch-control panel in related art is not suitable for touch-control panel with large size for implementing.

### SUMMARY

The instant disclosure provides a capacitive touch-control panel apparatus. The capacitive touch-control panel apparatus includes a hub circuit and a touch-control substrate, wherein the touch-control substrate has M touch-control areas which parallel to a first direction and insulate from each other. Each touch-control area includes an axial body and N electrodes. The axial body is electrically connected to the hub circuit through a first conductive line and the electrodes are disposed corresponding to the axial body and are electrically connected to the hub circuit through a plurality of second conductive lines, wherein the first conductive line electrically connected to each touch-control area and the plurality of second conductive lines does not intersect and the electrodes and the axial body generates effect of mutual capacitance. One of the electrodes in the each touch-control area is connected to one of the electrodes in the other touch-control area by one-to-one manner, wherein M, N are positive integers.

In an embodiment of the instant disclosure, the touch-control circuit is electrically connected to the touch-control areas through the hub circuit. The touch-control circuit is sequentially transmitting a plurality of driving scan signals to the axial bodies through the first conductive lines according to a plurality of predetermined scanning time, wherein the plurality of predetermined scanning time sequentially corresponds to the touch-control areas respectively.

In an embodiment of the instant disclosure, when voltage of at least one of the electrodes changes, the touch-control circuit acquires a coordinate of at least one touch-points according to voltage variation of each touch-control signal in the hub circuit and the touch-control areas corresponding to the plurality of predetermined scanning time.

In an embodiment of the instant disclosure, relationship of electrically connection in the hub circuit for one of the electrodes on the each touch-control area is that the electrodes paralleling to a second direction is electrically connected to each other and the second direction is substantially perpendicular to the first direction.

In summary, capacitive touch-control panel apparatus, provided by the embodiments of the instant disclosure, may reduce at least one mask for lithography process, efficiently reducing cost, weight and thickness of the touch-control panel and be suitable for touch-control panel with large size for implementing.

For further understanding of the instant disclosure, reference is made to the following detailed description illustrating the embodiments and examples of the instant disclosure. The description is only for illustrating the instant disclosure, not for limiting the scope of the claim.

### BRIEF DESCRIPTION OF THE DRAWINGS

FIG. 1A shows a schematic diagram of the capacitive touch-control panel apparatus according to one embodiment of the instant disclosure.

FIG. 1B shows a waveform diagram of the driving scan signal according to one embodiment of the instant disclosure.

FIG. 2 shows a detail schematic diagram of the capacitive touch-control panel apparatus according to another embodiment of the instant disclosure;

FIG. 3 shows a detail schematic diagram of the capacitive touch-control panel apparatus according to another one embodiment of the instant disclosure.

FIG. 4 and FIG. 5 show detailed schematic diagrams of the capacitive touch-control panel apparatus corresponding to FIG. 2 and FIG. 3 respectively, according to one embodiment of the instant disclosure.

FIG. 6 shows a schematic diagram of capacitive touch-control panel apparatus according to another one embodiment of the instant disclosure;

FIG. 7 shows a detailed schematic diagram of the capacitive touch-control panel apparatus according to yet another one embodiment of the instant disclosure.

FIG. 8 shows a detailed schematic diagram of the capacitive touch-control panel apparatus according to one embodiment of the instant disclosure.

### DETAILED DESCRIPTION OF PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings. In the drawings, the size and relative sizes of layers and regions may be exaggerated for clarity.

It will be understood that, although the terms first, second, third, and the like, may be used herein to describe various elements, components, regions, layers and/or sections, these elements, components, regions, layers and/or sections should not be limited by these terms. These terms are only to distinguish one element, component, region, layer or section from another region, layer or section discussed below could be termed a second element, component, region, layer or section without departing from the teachings of the instant disclosure. As used herein, the term “and/or” includes any and all combinations of one or more of the associated listed items.

### Embodiment of the Capacitive Touch-Control Panel Apparatus

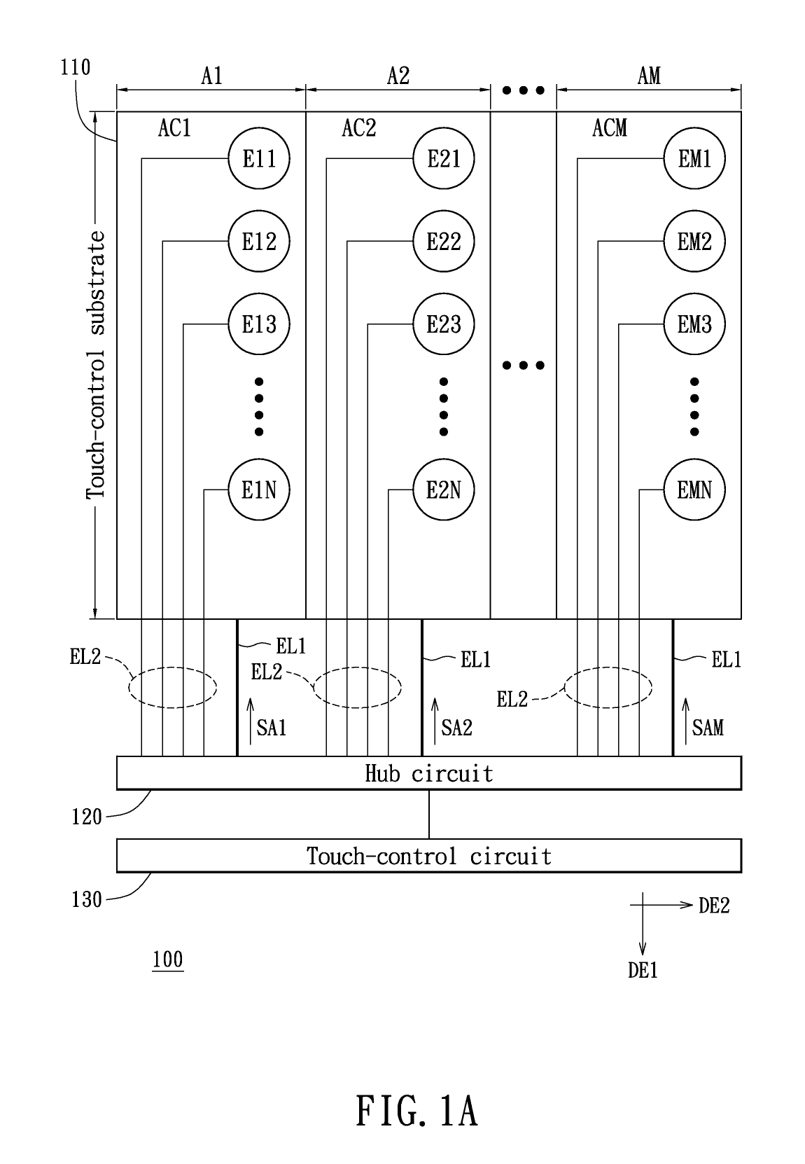

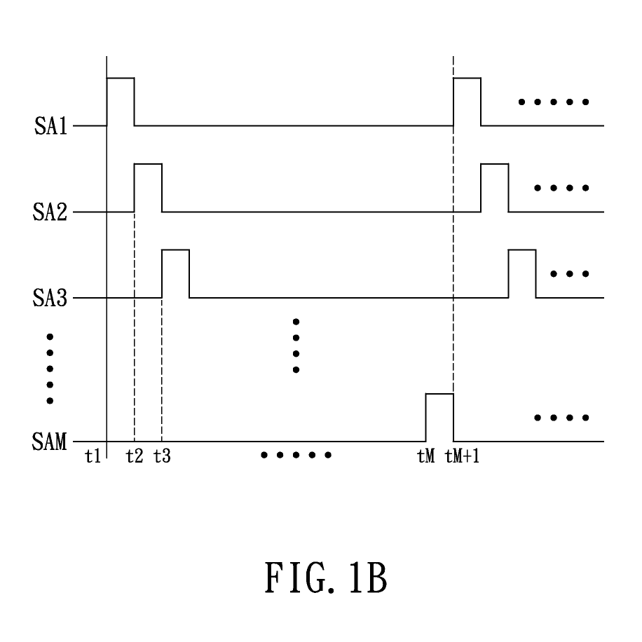

Referring to FIGS. 1A and 1B concurrently, FIG. 1A shows a schematic diagram of the capacitive touch-control panel apparatus according to one embodiment of the instant disclosure. FIG. 1B shows a driving waveform diagram of the driving scan signal according to one embodiment of the instant disclosure. The capacitive touch-control panel apparatus 100 of the instant disclosure includes a touch-control substrate 110 and a hub circuit 120, wherein the substrate of the touch-control substrate is transparent insulating material, such as glass or polyethylene. The touch-control substrate 110 has M touch-control areas A1˜AM which parallel to a first direction DE1 and insulate from each other. A first touch-control area A1 among the M touch-control areas A1˜AM includes a axial body AC1 and N electrodes E11˜E1N, and a second touch-control area A2 among the M touch-control areas A1˜AM includes a axial body AC2 and N electrodes E21˜E2N, and similarly, a touch-control area AM among the M touch-control areas A1˜AM includes a axial body ACM and N electrodes EM1˜EMN, wherein M, N is positive integer. In other words, the touch-control substrate 110 is formed with the axial bodies AC1˜ACM and the electrodes E11˜EMN. In addition, the capacitive touch-control panel apparatus 100 further includes a touch-control circuit 130 electrically connected to the hub circuit 120.

Each of the axial bodies AC1˜ACM is electrically connected to the hub circuit 120 respectively through one among a plurality of first conductive lines EL1. N electrodes are disposed corresponding to the axial bodies AC1˜ACM. For example, the N electrodes E11˜E1N is disposed corresponding to the axial body AC1, the N electrodes E21˜E2N is disposed corresponding to the axial body AC2, and similarly, the N electrodes EM1˜EMN is disposed corresponding to the axial body ACM. The electrodes E11˜EMN is electrically connected to the hub circuit 120 through a plurality of second conductive lines EL2 respectively. The touch-control circuit 130 is electrically connected to each of the touch-control areas A1˜AM through the hub circuit 120.

Moreover, the first conductive line EL1 of each of the touch-control areas A1˜AM and the second conductive lines EL2 does not intersect each other and the electrodes (e.g. E11˜E1N, E21˜E2N, . . . , EM1˜EMN) and the corresponding axial bodies (e.g. AC1˜ACM) thereof may generate effect of mutual capacitance. In other words, the electrodes E11˜E1N and the corresponding axial body AC1 thereof may generate effect of mutual capacitance, the electrodes E21˜E2N, the corresponding axial body AC2 thereof may generate effect of mutual capacitance, and similarly, the electrodes EM1˜EMN and the corresponding axial body ACM thereof may generate effect of mutual capacitance. One of the N electrodes (e.g. E11˜E1N) on the touch-control area (e.g. A1) may correspondingly be electrically connected to one of the electrodes (e.g. E21˜E2N, . . . , EM1˜EMN) on the other touch-control area (e.g. A2˜AM) each other in the hub circuit 120. In other words, each (e.g. E11) of the electrodes on each (e.g. A1) of the touch-control areas may correspondingly be electrically connected to one (e.g. E21, E31, . . . , EM1) of the electrodes on the other touch-control area in the hub circuit 120, so that the electrodes on the different touch-control areas are electrically connected to each other by one-to-one manner. Therefore, the touch-control signals of electrodes electrically connected to each other in the hub circuit 120 are collected as a sensing signal, in other words, the sensing signal includes the touch-control signals of the electrodes electrically connected to each other in the hub circuit 120.

For example, if the electrode E11 on the touch-control area A1 is electrically connected to the electrode E23 on the adjacent touch-control A2 by one-to-one manner, meanwhile, the electrode E11 does not be electrically connected to the other electrode (e.g. E21, E22, E24˜E2N) in the hub circuit 120. Similarly, the electrode E23 does not be electrically connected to the other electrode (e.g. E12˜E1N) in the hub circuit 120. Therefore, compared with the related art, the instant disclosure may reduce amount of the second conductive lines EL2 electrically connected to the touch-control circuit 130 by shorting the second conductive lines EL2 in the hub circuit 130 so as to significantly reduce the number of pins of the touch-control circuit 130, and thus the complexity and the cost for designing circuit may be decreased efficiently to implement the touch-control panel with large size.

Next, the touch-control circuit 130 sequentially transmits a plurality of driving scan signals SA1˜SAM to the corresponding axial body AC1˜ACM through the first conductive lines EL1 according to a plurality of predetermined scanning time t1˜tM. In other words, at the predetermined scanning time t1, the touch-control circuit 130 transmits the driving scan signal SA1 to the corresponding axial body AC1 through the first conductive line EL1; and at the predetermined scanning time t2, the touch-control circuit 130 transmits the driving scan signal SA2 to the corresponding axial body AC2 through the first conductive line EL1. Similarly, at the predetermined scanning time tM, the touch-control circuit 130 transmits the driving scan signal SAM to the corresponding axial body ACM through the first conductive line EL1. Accordingly, the touch-control circuit 130 may sense the coordinate of the touch point through scanning the whole capacitive touch-control panel.

When the voltage of at least one of the electrodes E11˜EMN changes, the touch-control circuit 130 may sense voltage variation of each touch-control signal in the hub circuit 120 and acquire at least one coordinate according to voltage variation of each touch-control signal in the hub circuit 120 and the touch-control areas corresponding to the predetermined scanning time t1˜tM. In short, the capacitive touch-control panel apparatus of the instant disclosure not only senses single point touch-control, but also senses multi-point touch-control effectively. What follows is further illustrating the action of the capacitive touch-control panel apparatus.

For example, when the user utilize a finger or a touch-control pen to touch at least one electrode of the capacitive touch-control panel apparatus 100, such as the electrodes E22 and E56, the potential of the electrodes E22 and E56 may generate variation due to field coupling effect of the finger or the touch-control pen so as to transmit the voltage variation of the touch-control signal of the electrodes E22 and E56 to the touch-control circuit 130 through electrically connection between the second conductive lines EL2 and the hub circuit 120.

Firstly, suppose a first direction is Y-axis and a second direction is X-axis hereinafter. The touch-control circuit 130 may acquire the Y coordinates of the two touch points according to the relationship of electrically connection for electrodes E22 and E56 in the hub circuit 120. The touch-control circuit 130 may further acquire the X coordinates of the two touch points according to the predetermined scanning time t1˜tM, wherein the touch-control circuit 130 transmits a plurality of driving scan signals SA1˜SAM to the corresponding touch-control areas A1˜AM so as to drive the axial bodies AC1˜ACM respectively through the first conductive lines EL1 according to a plurality of predetermined scanning time t1˜tM. In other words, the touch-control circuit 130 may transmit the driving scan signal SA2 to the touch-control area A2 at the predetermined scanning time t2 and sense the voltage variation of the touch-control signal of the electrode E22. The touch-control circuit 130 may transmit the driving scan signal SA5 to the touch-control area A5 at the predetermined scanning time t5 and sense the voltage variation of the touch-control signal of the electrode E56. Therefore, the touch-control circuit 130 may precisely position the touch location of the touch point.

Compared with the prior art, in the embodiment of the instant disclosure, the designer may arrange the relationship of electrically connection in the hub circuit 120 for the first conductive lines EL1 and the second conductive lines EL2 according to the demand of the circuit design and actual performance. Accordingly, the instant disclosure not only may precisely position the touch location of the touch point, but also significantly reduce the number of pin between the metal conductive line and touch-control circuit so as to decrease the complexity of circuit design. Furthermore, in the capacitive touch-control plane apparatus 100 of the instant disclosure, the electrodes E11˜EMN and the axial bodies AC1˜ACM may be disposed on the same plane of a single-layer. In other words, the instant disclosure does not need the bridge connection and be capable of reducing at least one mask for lithography process so as to significantly decrease the cost of circuit manufacturing and circuit design.

Furthermore, in one embodiment, the relationship of electrically connection in the hub circuit for one of the electrodes on the each touch-control area and one of the electrodes on the other touch-control area is that the electrodes paralleling to a second direction DE2 are electrically connected to each other and the second direction DE2 is substantially perpendicular to the first direction DE1. In other words, the electrodes in each column or in each row are electrically connected to each other in the hub circuit 120 (i.e. shorting or having the equal potential). For example, the electrodes E11, E21, . . . , EM1 are electrically connected to each other in the hub circuit 120, the electrodes E12, E22, . . . , EM2 are electrically connected to each other in the hub circuit 120, and similarly, the electrodes E1N, E2N, . . . , EMN are electrically connected to each other in the hub circuit 120, but the embodiment is not restricted thereto. In short, without departing from the spirit of electrically connection by one-to-one manner for one of the electrodes on each touch-control area and one of the electrodes on the other touch-control area, the scope disclosed all belongs to the thoughts of technology of the present disclosure.

In the follow-up embodiments, the instant disclosure will describe the part which is different from aforementioned embodiment of FIG. 1A and FIG. 1B, and the components same as aforementioned embodiments of FIG. 1A and FIG. 1B are thus omitted. Furthermore, similar reference numeral or mark indicate similar reference device for ease of explanation.

### Another Embodiment of the Capacitive Touch-Control Panel Apparatus

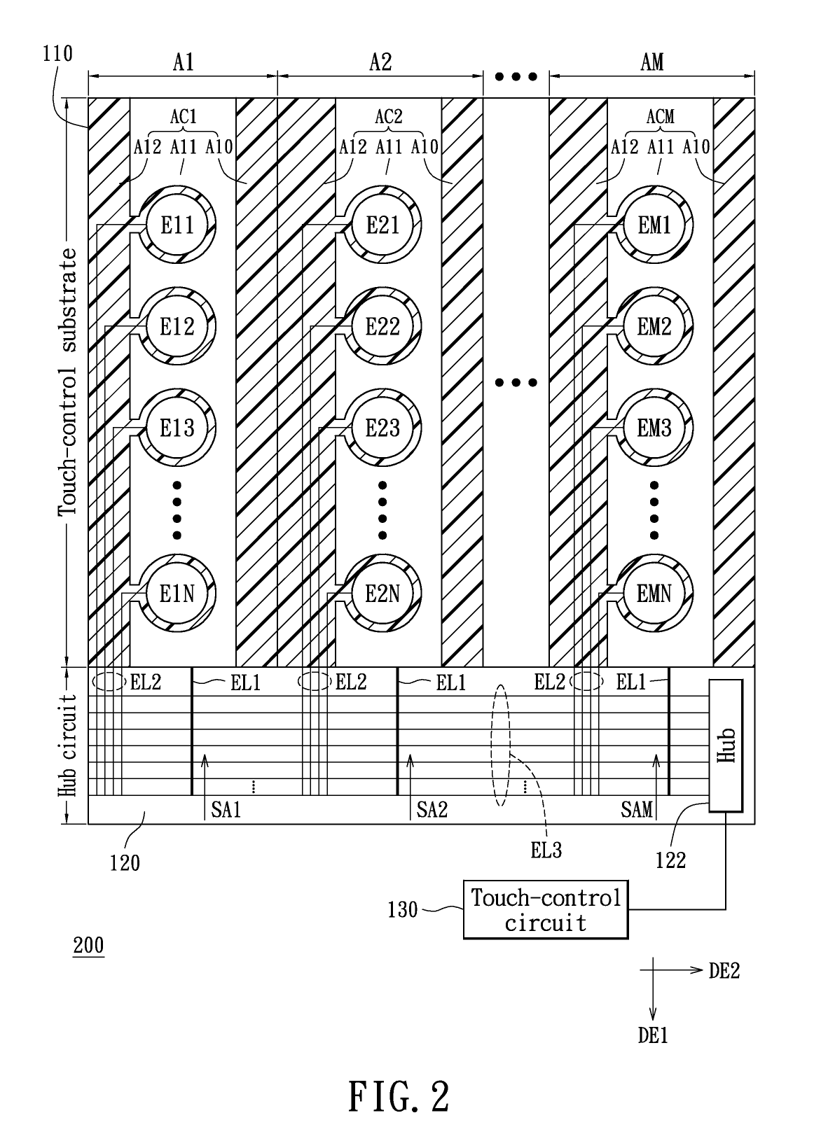

Referring to FIG. 2, FIG. 2 shows a detail schematic diagram of the capacitive touch-control panel apparatus according to another embodiment of the instant disclosure. The differences compared with aforementioned embodiments in FIG. 1A and FIG. 1B are that the hub circuit 120 of the present embodiment is a flexible printed circuit board (FPC) and the FPC includes a plurality of first conductive lines EL1, a plurality of second conductive lines EL2, a plurality of third conductive lines EL3 and a hub 122. The plurality of third conductive lines EL3 are electrically connected to the plurality of first conductive lines EL1 and the plurality of second conductive lines EL2. The hub 122 is electrically connected to the touch-control circuit 130 and the hub 122 is used for collecting the plurality of third conductive lines EL3. The axial bodies AC1˜ACM respectively includes a first insulating area A10, a first conductive area A11 and a second insulating area A12.

The first conductive areas A11 are electrically connected to the hub circuit 120 through the corresponding first conductive lines EL1 respectively. The electrodes (e.g. E11˜E1N, E21˜E2N, . . . , EM1˜EMN) of each touch-control area are respectively disposed in the corresponding second insulating area A12. In other words, the electrodes E11˜E1N are disposed in the corresponding second insulating area A12 of the axial body AC1, the electrodes E211˜E2N are disposed in the corresponding second insulating area A12 of the axial body AC2, and similarly, the electrodes EM1˜EMN are disposed in the corresponding second insulating area A12 of the axial body ACM.

The electrodes (e.g. E11˜E1N, E21˜E2N, . . . , EM1˜EMN) are connected to the hub circuit 120 respectively through the second conductive lines EL2, and it is worth to be noted that the second insulating area A12 is smaller than the first insulating area A10 in the present embodiment, but the embodiment is not restricted thereto. In the present embodiment, the second conductive lines EL2 are disposed on the second insulating areas A12, and in another one embodiment, the second conductive lines EL2 are disposed on the first insulating areas A10, but the present embodiment is not restricted thereto. In the axial bodies AC1˜ACM, the second conductive lines EL2 are disposed on the second insulating area A12, in another embodiment, the second conductive lines EL2 are disposed on the first insulating area A10, but the present embodiment is not restricted thereto. Moreover, when the touch-control circuit 130 transmits the plurality of driving scan signals SA1˜SAM to the corresponding first conductive area A11 respectively, the electrodes (e.g. E11˜E1N, E21˜E2N, . . . , EM1˜EMN) and the corresponding first conductive area A11 may generate mutual capacitance each other.

In other words, the electrodes E11˜E1N and the first conductive area A11 of the axial body AC1 may generate mutual capacitance, the electrodes E21˜E2N and the first conductive area A11 of the axial body AC2 may generate mutual capacitance, and similarly, the electrodes EM1˜EMN and the first conductive area A11 of the axial body ACM may generate mutual capacitance. Incidentally, in this embodiment, the material of the first conductive area A11 and the electrodes (e.g. E11˜E1N, E21˜E2N, . . . , EM1˜EMN) both are the transparent conductive film and the transparent conductive film may be an indium tin oxide (ITO), indium zinc oxide (IZO) or antimony tin oxide (ATO). The material of the first insulating area A10 and the second insulating area A12 is glass, polyethylene or a material with non-conductive and transparent characteristic.

In the embodiment of the instant disclosure, the touch-control substrate 110 of the capacitive touch-control panel apparatus 200 is divided into a plurality of touch-control areas A1˜AM through the first insulating area A10, and each of the axial bodies AC1˜ACM on the touch-control area is divided into the first insulating area A10, the first conductive area A11 and the second insulating area A12. Accordingly, the touch-control circuit 130 may be capable of driving each of the touch-control area A1˜AM, in other words, the touch-control circuit 130 transmits the plurality of driving scan signals SA1˜SAM to the corresponding first conductive areas A11 through the first conductive lines EL1 so as to drive each of the touch-control area A1˜AM.

The second conductive lines EL2 electrically connected to the electrodes (e.g. E11˜E1N, E21˜E2N, . . . , EM1˜EMN) may be arranged by the designer for shorting in the hub circuit 120 according to the demand of circuit design. In other words, when the electrodes disposed on the same column or the same row are connected to the same third conductive line EL3, the electrodes, such as E11, E21, . . . , EM1, may be regard as shorting each other or may have the same potential. Next, the hub 122 may be electrically connected to the touch-control circuit 130 through a bus, so that the touch-control circuit 130 may receive touch-control signal and transmit the plurality of driving scan signals SA1˜SAM. Accordingly, the capacitive touch-control apparatus 200 may not only reduce the amount of the second conductive lines EL2 directly connected to the touch-control circuit 130, but also significantly decrease the complexity of the circuit design. Moreover, the capacitive touch-control apparatus 200 may precisely position the coordinate of the touch point according to the sensing mechanism of the embodiment in FIG. 1A.

In the follow-up embodiments, the instant disclosure will describe the part different from aforementioned embodiments of FIG. 2 and other ignoring part is the same as aforementioned embodiments of FIG. 2. Furthermore, similar reference numeral or mark indicate similar reference device for ease of explanation.

### Another Embodiment of the Capacitive Touch-Control Panel Apparatus

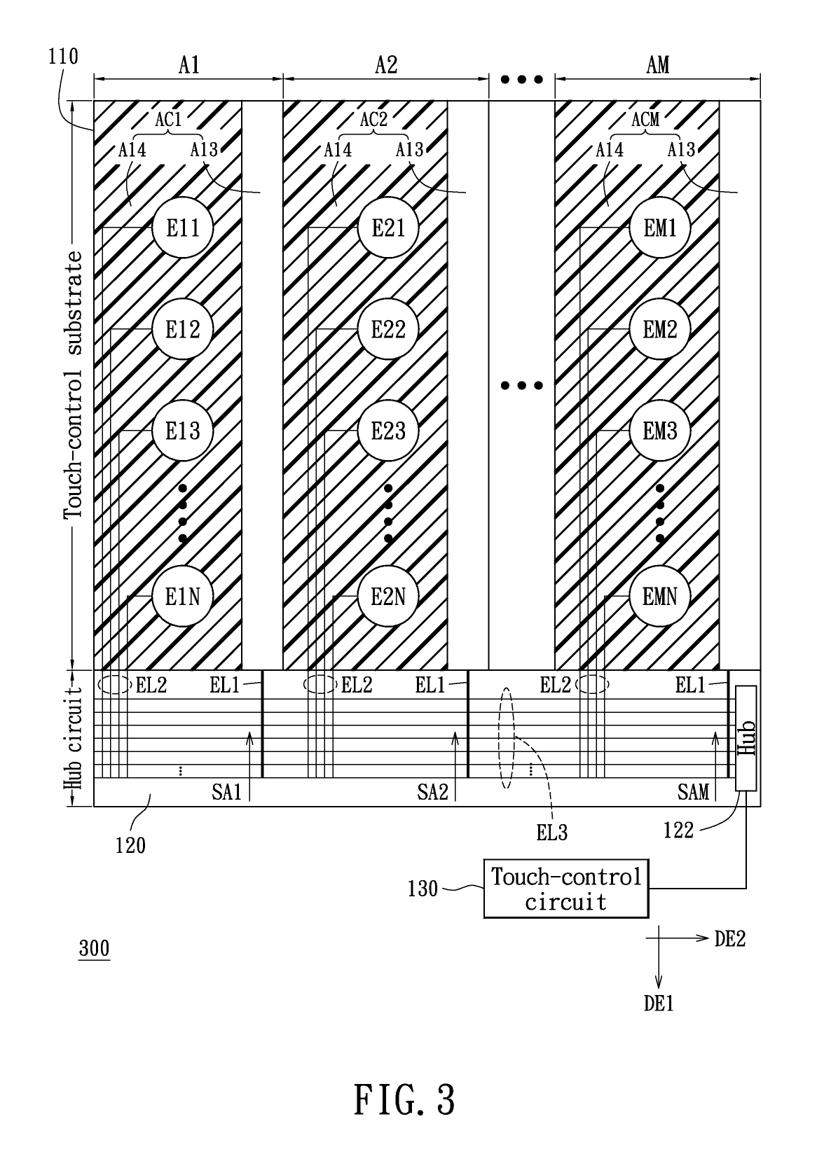

Referring to FIG. 3, FIG. 3 shows a detail schematic diagram of the capacitive touch-control panel apparatus according to another embodiment of the instant disclosure. The differences compared with aforementioned embodiments in FIG. 2 are that each of the axial bodies AC1˜ACM respectively includes a second conductive area A13 and a third insulating area A14.

The second conductive areas A13 are electrically connected to the hub circuit 120 respectively through the corresponding first conductive line EL1. The electrodes (e.g. E11˜E1N, E21˜E2N, . . . , EM1˜EMN) are respectively disposed within the third insulating area A14. In other words, the electrodes E11˜E1N are disposed within the third insulating area A14 of the axial body AC1, the electrodes E21˜E2N are disposed within the third insulating area A14 of the axial body AC2, and similarly, the electrodes EM1˜EMN are disposed within the third insulating area A14 of the axial body ACM.

Moreover, the electrodes (e.g. E11˜E1N, E21˜E2N, . . . , EM1˜EMN) are electrically connected to the hub circuit 120 through the second conductive lines EL2 respectively. In the each of the axial bodies AC1˜ACM, the first conductive line EL1 is disposed on the third insulating area A14. When the touch-control circuit 130 respectively transmits the plurality of driving scan signals SA1˜SAM to the corresponding second conductive area A13, the electrodes (e.g. E11˜E1N, E21˜E2N, . . . , EM1˜EMN) and the corresponding second conductive area A13 may generate mutual capacitance. Incidentally, in this embodiment, the material of the second conductive area A13 and the electrodes (e.g. E11˜E1N, E21˜E2N, . . . , EM1˜EMN) both are the transparent conductive film and the transparent conductive film may be an indium tin oxide (ITO), indium zinc oxide (IZO) or antimony tin oxide (ATO). The material of the third insulating area A14 is glass, polyethylene or a material with non-conductive and transparent characteristic.

In the embodiment of the instant disclosure, the touch-control substrate 110 of the capacitive touch-control panel apparatus 200 is divided into a plurality of touch-control areas A1˜AM, and each of the axial bodies AC1˜ACM on the touch-control area is divided into the second conductive area A13 and the third insulating area A14. Therefore, the touch-control circuit 130 may be capable of driving each of the touch-control area A1˜AM, in other words, the touch-control circuit 130 transmits the plurality of driving scan signals SA1˜SAM to the corresponding second conductive areas A13 through the first conductive lines EL1 so as to drive each of the touch-control areas A1˜AM.

The second conductive lines EL2 electrically connected to the electrodes (e.g. E11˜E1N, E21˜E2N, . . . , EM1˜EMN) may be arranged by the designer for shorting in the hub circuit 120 according to the demand of circuit design. In other words, when the electrodes disposed on the same column or the same row are connected to the same third conductive line EL3, the electrodes, such as E11, E21, . . . , EM1, may be regard as shorting each other or may have the same potential. Next, the hub 122 may be electrically connected to the touch-control circuit 130 through a bus, so that the touch-control circuit 130 may receive touch-control signal and transmit the plurality of driving scan signals SA1˜SAM. Accordingly, the capacitive touch-control apparatus 200 may not only reduce the amount of the second conductive line directly connected to the touch-control circuit 130, but also significantly decrease the complexity of the circuit design. Moreover, the capacitive touch-control apparatus 200 may precisely position the coordinate of the touch point according to the sensing mechanism of the embodiment in FIG. 1A.

### Another Embodiment of the Capacitive Touch-Control Panel Apparatus

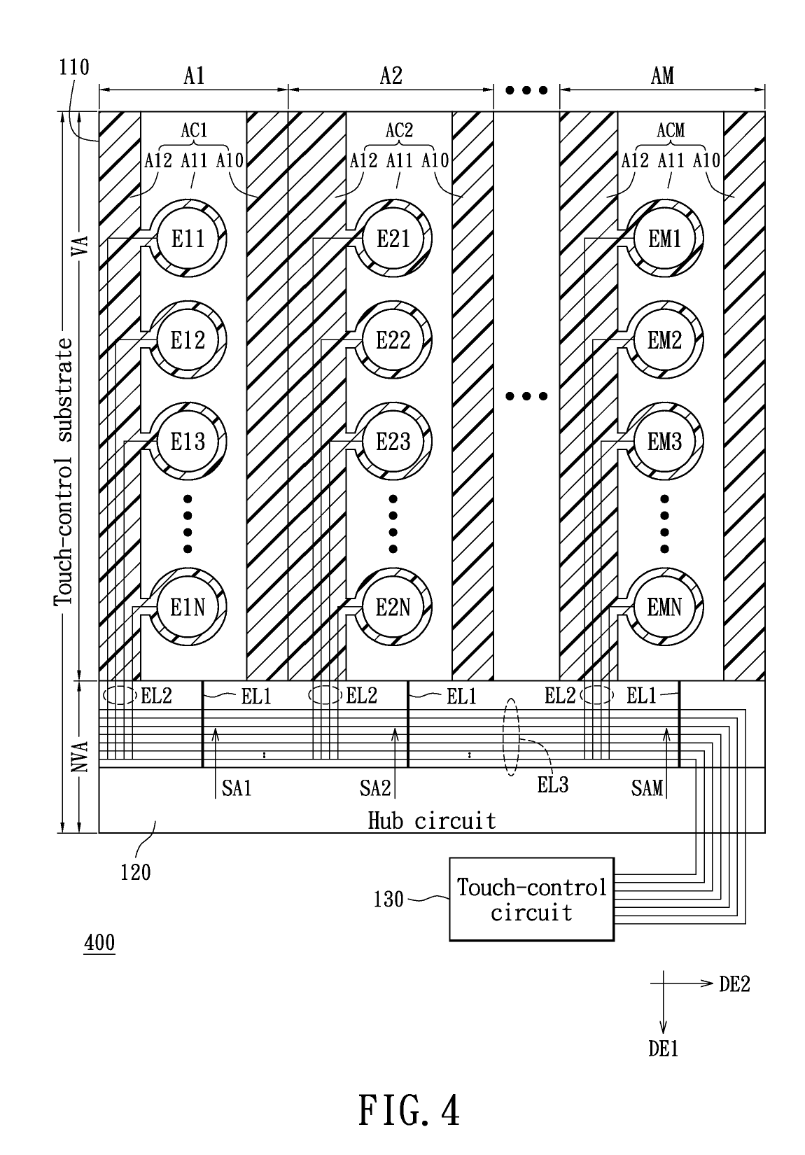

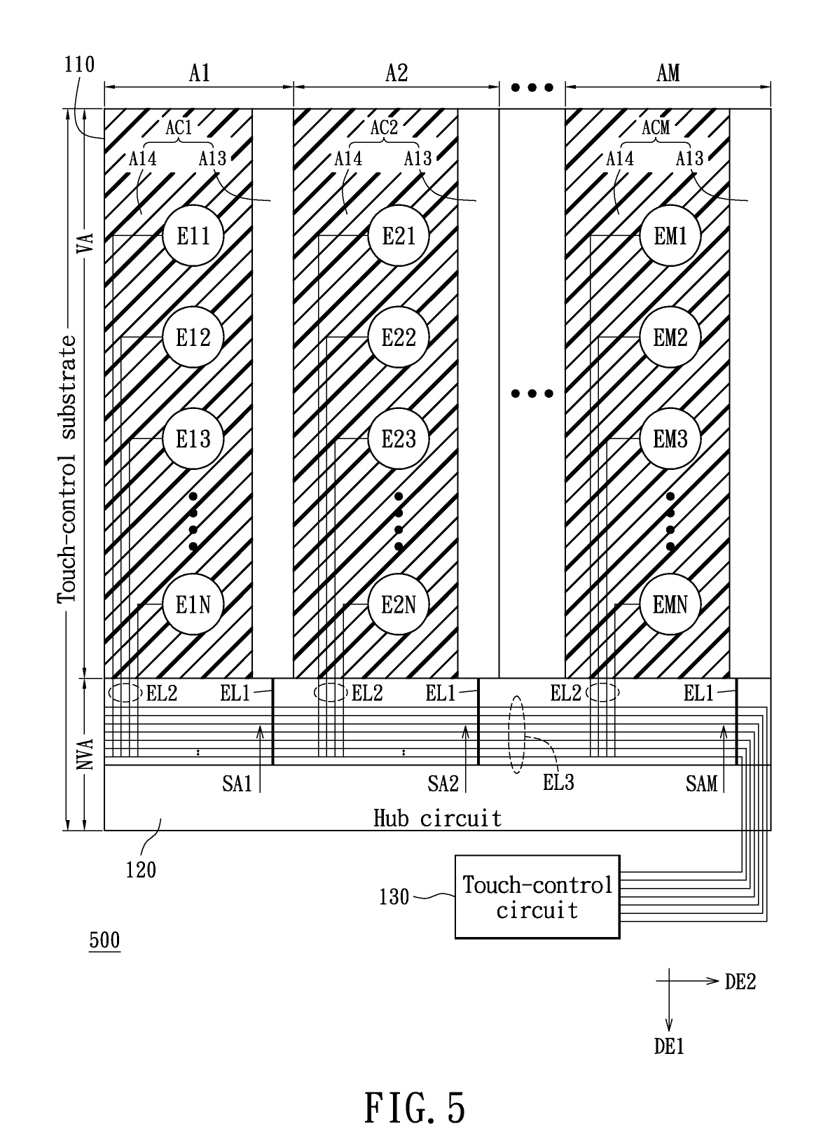

Referring to FIG. 4 and FIG. 5, FIG. 4 and FIG. 5 show detailed schematic diagrams of the capacitive touch-control panel apparatus corresponding to FIG. 2 and FIG. 3 respectively, according to one embodiment of the instant disclosure. The differences compared with aforementioned embodiments in FIG. 2 and FIG. 3 are that the hub circuit 120 is directly disposed on the non-visible region NVA of the touch-control substrate 110 and the electrodes E11˜EMN are disposed on the visible region VA of the touch-control substrate 110. The hub circuit 120 includes a plurality of third conductive lines EL3, a plurality of second conductive lines EL2 and the touch-control circuit 130, wherein the plurality of third conductive lines EL3 are electrically connected to the plurality of first conductive lines EL1. The mechanism of the embodiments in FIG. 4 and FIG. 5 is the same as the operation of the embodiments in FIG. 2 and FIG. 3 substantially, so people skilled in the art would be able to comprehend and further descriptions are therefore omitted.

In addition, compared with the aforementioned embodiments in FIG. 2 and FIG. 3, because the hub circuit of the embodiment in FIGS. 4 and 5 is disposed on the non-visible area NVA of the touch-control substrate 110, the capacitive touch-control panel apparatus may not only precisely position the touch location of the touch point, but also significantly reduce the amount of the pins used for connecting the metal conductive line and the touch-control circuit 130 and decrease the complexity of circuit design. Furthermore, the instant disclosure may save a cost of manufacturing FPC.

### Another Embodiment of the Capacitive Touch-Control Panel Apparatus

What follows is to further teach the capacitive touch-control panel apparatus relating that the hub circuit and touch-control circuit are directly embedded in the touch-control substrate with the technology of chip-on-glass (COG).

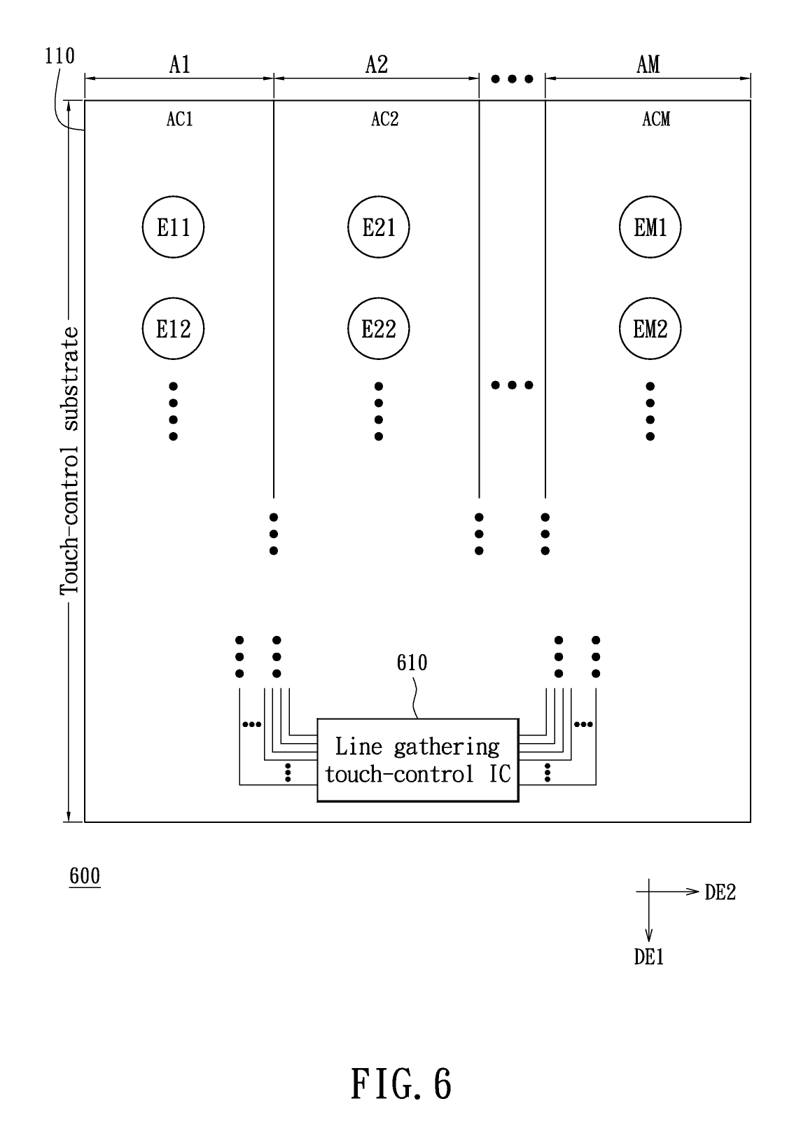

Referring to FIG. 6, FIG. 6 shows a schematic diagram of capacitive touch-control panel apparatus according to another one embodiment of the instant disclosure. In this embodiment, the hub circuit and touch-control circuit are manufactured together in a hub touch-control circuit integrated circuit 610. In other words, the hub circuit and touch-control circuit are manufactured together in the same IC chip by the means of integrated circuit, and then the IC chip is embedded in the touch-control substrate 110 with the technology of COG, but the embodiment is not restricted thereto. Moreover, if the touch-control substrate is an outer shell protection glass for general electronic apparatus, it may save a manufacturing cost for the touch-control panel. In other words, it may integrate the touch-control panel layer and the outer shell protection layer into the same touch-control substrate 110 in at least one of the embodiments of instant disclosure. Accordingly, it may reduce the weight, thickness and manufacturing cost for the capacitive touch-control panel apparatus. It is worth mentioning that the aforementioned outer shell protection glass also may be other kind of outer shell protection layer with transparent and insulating characteristic and the hub circuit and touch-control circuit may also be embedded in the outer shell protection layer.

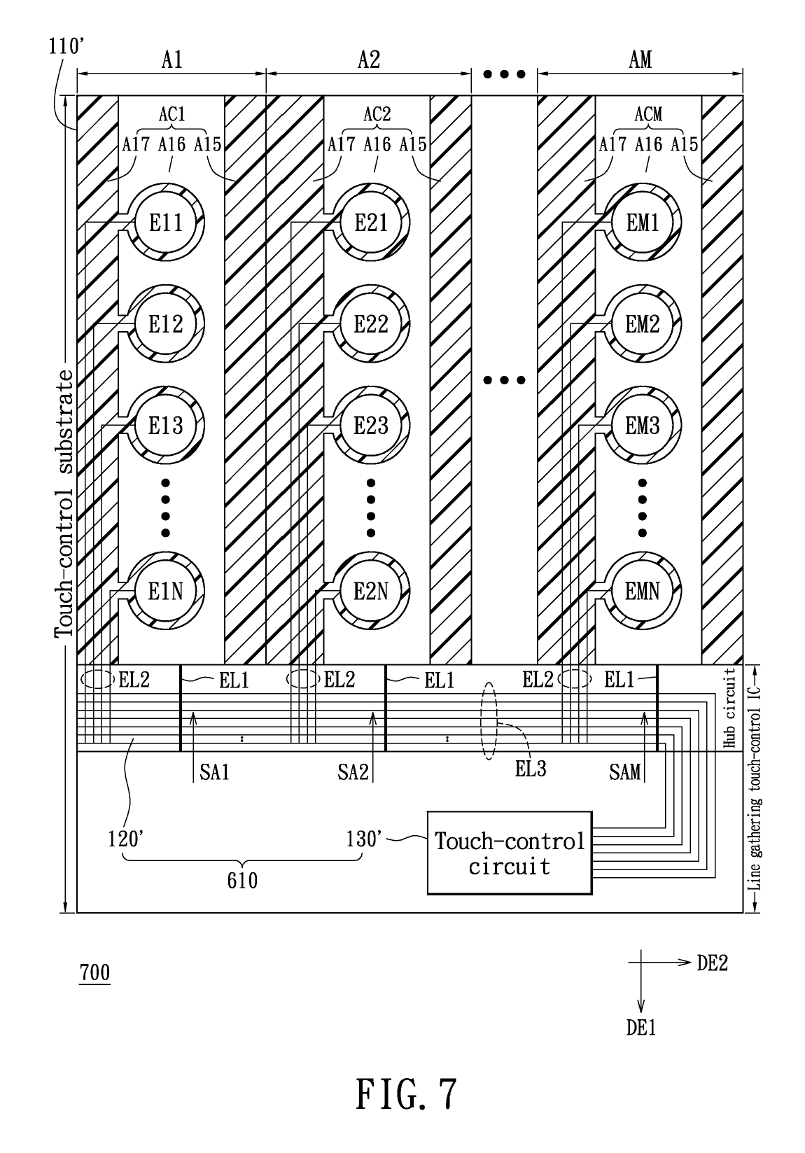

Referring to FIG. 7, FIG. 7 shows a detailed schematic diagram of the capacitive touch-control panel apparatus according to yet another one embodiment of the instant disclosure. In this embodiment, the hub touch-control IC 160 including a hub circuit 120′ and a touch-control circuit 130′ is directly embedded in or disposed in the touch-control substrate 110′ with the technology of the COG. In one embodiment, the substrate itself may also be served as outer shell protection glass. As shown in FIG. 7, the hub circuit 120′ includes a plurality of third conductive lines EL3 and the hub circuit 120′ is electrically connected to a plurality of first conductive lines EL1, a plurality of second conductive lines EL2 and a touch-control circuit 130′. Each of the axial bodies AC1˜ACM includes a fourth insulating area A15, a third conductive area A16 and a fifth insulating area A17.

The third conductive areas A16 are electrically connected to the hub circuit 120′ through the corresponding first conductive line EL1. The N electrodes (e.g. E11˜E1N, E21˜E2N, . . . , EM1˜EMN) are disposed within fifth insulating area A17. In other words, the N electrodes E11˜E1N are disposed within the fifth insulating area A17 of the axial body AC1, the N electrodes E21˜E2N are disposed within the fifth insulating area A17 of the axial body AC2, and similarly, the N electrodes EM1˜EMN are disposed within the fifth insulating area A17 of the axial body ACM.

The electrodes (e.g. E11˜E1N, E21˜E2N, . . . , EM1˜EMN) are electrically connected to the hub circuit 120′ through the second conductive lines EL2 respectively, wherein it is worth to be noted that the fifth insulating area A17 is smaller than fourth insulating area A15, but the embodiment is not restricted thereto. In the each of the axial bodies AC1˜ACM, the first conductive line EL1 is disposed on the fifth insulating area A17, and in another one embodiment, the first conductive line EL1 is disposed on the fourth insulating area A15, but the embodiment is not restricted thereto. Moreover, when the touch-control circuit 130′ respectively transmits the plurality of driving scan signals SA1˜SAM to the corresponding third conductive line EL3, the electrodes (e.g. E11˜E1N, E21˜E2N, . . . , EM1˜EMN) and the corresponding third conductive area A16 may generate mutual capacitance respectively.

In other words, the electrodes E11˜E1N and the third conductive area A16 of the axial body AC1 may generate mutual capacitance, the electrodes E21˜E2N and the third conductive area A16 of the axial body AC2 may generate mutual capacitance, and similarly, the electrodes EM1˜EMN and the third conductive area A 16 of the axial body ACM may generate mutual capacitance.

Incidentally, in this embodiment, a material of the third conductive area A16 and the electrodes (e.g. E11˜E1N, E21˜E2N, . . . , EM1˜EMN) both are the transparent conductive film and the transparent conductive film may be an indium tin oxide (ITO), indium zinc oxide (IZO) or antimony tin oxide (ATO). The material of the fourth insulating area A15 and the second insulating area A12 is glass, polyethylene or a material with non-conductive and transparent characteristic.

In the embodiment of instant disclosure, the touch-control substrate 110′ of the capacitive touch-control panel apparatus 700 is divided into a plurality of touch-control areas A1˜AM, and each of the axial bodies AC1˜ACM on the touch-control area is divided into the fourth insulating area A15, the third conductive area A16 and the fifth insulating area A17. Accordingly, the touch-control circuit 130′ may be capable of driving each of the touch-control area A1˜AM respectively, in other words, the touch-control circuit 130 transmits the plurality of driving scan signals SA1˜SAM to the corresponding third conductive area A16 through the first conductive lines EL1 so as to drive each of the touch-control area A1˜AM.

The second conductive lines EL2 electrically connected to the electrodes (e.g. E11˜E1N, E21˜E2N, . . . , EM1˜EMN) may be arranged by the designer for shorting in the hub circuit 120 according to the demand of circuit design. In other words, when the electrodes disposed on the same column or the same row are connected to the same third conductive line EL3, the electrodes, such as E11, E21, . . . , EM1, may be regard as shorting each other or may have the same potential. Next, the third conductive lines EL3 are electrically connected to the touch-control circuit 130′ so that the touch-control circuit 130′ may receive touch signal and transmit the plurality of driving scan signals SA1˜SAM. Accordingly, the capacitive touch-control apparatus 700 may not only reduce the amount of the second conductive lines EL2 directly connected to the touch-control circuit 130′, but also significantly decrease the complexity of the circuit design. Moreover, the capacitive touch-control apparatus 700 may precisely position the coordinate of the touch point according to the sensing mechanism of the embodiment in FIG. 1A.

In the follow-up embodiments, the instant disclosure will describe the part which is different from aforementioned embodiments of FIG. 7 and other ignoring part is the same as aforementioned embodiments of FIG. 7. Furthermore, similar reference numeral or mark indicate similar reference device for ease of explanation.

### One Embodiment of the Capacitive Touch-Control Panel Apparatus

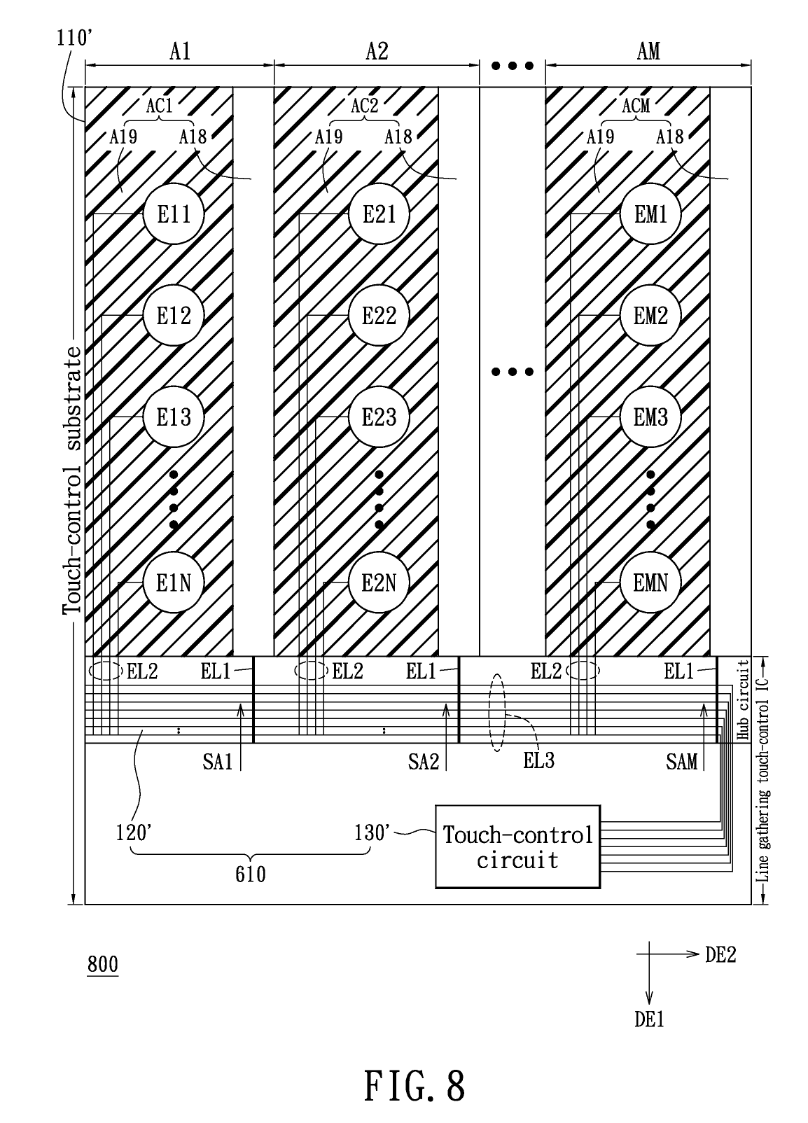

Referring to FIG. 8, FIG. 8 shows a detailed schematic diagram of the capacitive touch-control panel apparatus according to one embodiment of the instant disclosure. The differences compared with aforementioned embodiment in FIG. 7 are that each of the axial bodies in this embodiment includes a fourth conductive area A18 and a sixth insulating area A19.

The fourth conductive areas A18 are electrically connected to the hub circuit 120′ through the corresponding first conductive lines EL1 respectively. The electrodes (e.g. E11˜E1N, E21˜E2N, . . . , EM1˜EMN) are respectively disposed in the corresponding sixth insulating area A19. In other words, the electrodes E11˜E1N are disposed in the corresponding sixth insulating area A19 of the axial body AC1, the electrodes E21˜E2N are disposed in the corresponding sixth insulating area A19 of the axial body AC2, and similarly, the electrodes EM1˜EMN are disposed in the corresponding sixth insulating area A19 of the axial body ACM.

The electrodes (e.g. E11˜E1N, E21˜E2N, . . . , EM1˜EMN) are connected to the hub circuit 120′ respectively through the second conductive lines EL2. In the each of the axial bodies AC1˜ACM, the second conductive lines EL2 are disposed on the sixth insulating area A19. Moreover, when the touch-control circuit 130′ transmits the plurality of driving scan signals SA1˜SAM to the corresponding fourth conductive area A18 respectively, the electrodes (e.g. E11˜E1N, E21˜E2N, . . . , EM1˜EMN) and the corresponding fourth conductive area A18 may generate mutual capacitance each other. Incidentally, in the embodiment, the material of the fourth conductive area A18 and the electrodes (e.g. E11˜E1N, E21˜E2N, . . . , EM1˜EMN) both are the transparent conductive film and the transparent conductive film may be an indium tin oxide (ITO), indium zinc oxide (IZO) or antimony tin oxide (ATO). The material of the sixth insulating area A19 is glass, polyethylene or a material with non-conductive and transparent characteristic.

In the embodiment of the instant disclosure, the touch-control substrate 110′ of the capacitive touch-control panel apparatus 800 is divided into a plurality of touch-control areas A1˜AM, and each of the axial bodies AC1˜ACM on the touch-control area is divided into the fourth conductive area A18 and the sixth insulating area A19. Accordingly, the touch-control circuit 130′ may be capable of driving each of the touch-control area A1˜AM respectively, in other words, the touch-control circuit 130′ transmits the plurality of driving scan signals SA1˜SAM to the corresponding fourth conductive area A18 through the first conductive lines EL1 so as to drive each of the touch-control area A1˜AM.

The second conductive lines EL2 electrically connected to the electrodes (e.g. E11˜E1N, E21˜E2N, . . . , EM1˜EMN) may be arranged by the designer for shorting in the hub circuit 120 according to the demand of circuit design. In other words, when the electrodes disposed on the same column or the same row are connected to the same third conductive line EL3, the electrodes, such as E11, E21, . . . , EM1, may be regard as shorting each other or may have the same potential. Next, the third conductive lines EL3 are electrically connected to touch-control circuit 130′ so that the touch-control circuit 130′ may receive touch signal and transmit the plurality of driving scan signals SA1˜SAM. Accordingly, the capacitive touch-control apparatus 800 may not only reduce the amount of the second conductive lines EL2 directly connected to the touch-control circuit 130′, but also significantly decrease the complexity of the circuit design. Moreover, the capacitive touch-control apparatus 800 may precisely position the coordinate of the touch point according to the sensing mechanism of the embodiment in FIG. 1A.

To sum up, the capacitive touch-control panel apparatus is disclosed in the aforementioned embodiments of the instant disclosure. One of the electrodes in the each touch-control area is connected to one of the electrodes in the other touch-control area by one-to-one manner. In addition, the touch-control circuit sequentially transmits a plurality of driving scan signals to the corresponding axial body through the corresponding first conductive line according to the predetermined scanning time. Next, when voltage of at least one of the electrodes changes, the touch-control circuit acquires a coordinate of at least one touch-point according to voltage variation of each touch-control signal in the hub circuit and the touch-control areas corresponds to the plurality of predetermined scanning time. Accordingly, it may reduce at least one mask for lithography process, efficiently reduce cost, weight and thickness of the touch-control panel and be liable to implement the touch-control panel with large size.

In at least one of the embodiments of the instant disclosure, the capacitive touch-control panel apparatus not only may precisely position the touch location of the touch point, but also significantly reduce the number of pin between the metal conductive line and touch-control circuit so as to decrease the complexity of circuit design. Furthermore, the instant disclosure may save a cost of manufacturing flexible printed circuit board (FPC).

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A capacitive touch-control panel apparatus, comprising:
a hub circuit; and
a touch-control substrate, having M touch-control areas which parallel to a first direction and insulate from each other, wherein M is a positive integer and each touch-control area comprises:
an axial body, electrically connected to the hub circuit through a first conductive line; and
N electrodes, disposed corresponding to the axial body and electrically connected to the hub circuit through a plurality of second conductive lines, wherein the first conductive line electrically connected to each touch-control area and the plurality of second conductive lines does not intersect, and the electrodes and the axial body generates effect of mutual capacitance, wherein one of the electrodes on the each touch-control area is connected to one of the electrodes on the other touch-control area by one-to-one manner, wherein N is positive integer.

2. The capacitive touch-control panel apparatus according to claim 1, further comprising:
a touch-control circuit, electrically connected to the touch-control areas through the hub circuit, the touch-control circuit sequentially transmitting a plurality of driving scan signals to the axial bodies through the first conductive lines according to a plurality of predetermined scanning time, wherein the plurality of predetermined scanning time sequentially corresponds to the touch-control areas respectively.

3. The capacitive touch-control panel apparatus according to claim 1, wherein when voltage of at least one of the electrodes changes, the touch-control circuit acquires a coordinate of at least one touch-point according to voltage variation of each touch-control signal in the hub circuit and the touch-control areas corresponds to the plurality of predetermined scanning time.

4. The capacitive touch-control panel apparatus according to claim 1, wherein relationship of electrically connection in the hub circuit for one of the electrodes on the each touch-control area is that the electrodes paralleling to a second direction is electrically connected to each other and the second direction is substantially perpendicular to the first direction.

5. The capacitive touch-control panel apparatus according to claim 2, wherein the hub circuit, the first conductive lines and the plurality of the second conductive lines are implemented in a flexible printed circuit board (FPC) and the flexible printed circuit board comprises:
a plurality of third conductive lines, electrically connected to the first conductive lines and the plurality of second conductive lines; and
a hub, electrically connected to the touch-control circuit, the hub collecting the plurality of third conductive lines.

6. The capacitive touch-control panel apparatus according to claim 2, wherein the hub circuit is disposed on the non-visible region of the touch-control substrate and the hub circuit comprises:
a plurality of third conductive lines, electrically connected to the first conductive lines, the plurality of the second conductive lines and the touch-control circuit.

7. The capacitive touch-control panel apparatus according to claim 5, wherein each axial body comprises:
a first insulating area;
a first conductive area, electrically connected to the hub circuit through one of the first conductive lines, the first conductive area receiving one of the plurality of the driving scan signals; and
a second insulating area, wherein the electrodes of each touch-control area are disposed in the second insulating area, the electrodes are electrically connected to the hub circuit respectively through the plurality of second conductive lines, wherein the second insulating area is smaller than the first insulating area.

8. The capacitive touch-control panel apparatus according to claim 6, wherein each axial body comprises:
a first insulating area;
a first conductive area, electrically connected to the hub circuit through one of the first conductive lines, the first conductive area receiving one of the plurality of the driving scan signals; and
a second insulating area, wherein the electrodes of each touch-control area are disposed in the second insulating area, the electrodes are electrically connected to the hub circuit respectively through the plurality of second conductive lines, wherein the second insulating area is smaller than the first insulating area.

9. The capacitive touch-control panel apparatus according to claim 7, wherein the second conductive lines is disposed on the second insulating area and the electrodes and the first conductive area generate mutual capacitance each other.

10. The capacitive touch-control panel apparatus according to claim 7, wherein a material of the first conductive area and the electrodes is transparent conductive film and a material of the first insulating area and the second insulating area is glass or polyethylene.

11. The capacitive touch-control panel apparatus according to claim 8, wherein the second conductive lines is disposed on the second insulating area and the electrodes and the first conductive area generate mutual capacitance each other.

12. The capacitive touch-control panel apparatus according to claim 8, wherein a material of the first conductive area and the electrodes is transparent conductive film and a material of the first insulating area and the second insulating area is glass or polyethylene.

13. The capacitive touch-control panel apparatus according to claim 5, wherein each axial body comprises:
a second conductive area, electrically connected to the hub circuit through one of the first conductive lines, the second conductive area receiving one of the plurality of driving scan signals; and
a third insulating area, wherein the electrodes of each touch-control area are disposed in the third insulating area and the electrodes are electrically connected to the hub circuit respectively through the plurality of second conductive lines.

14. The capacitive touch-control panel apparatus according to claim 6, wherein each axial body comprises:
a second conductive area, electrically connected to the hub circuit through one of the first conductive lines, the second conductive area receiving one of the plurality of driving scan signals; and
a third insulating area, wherein the electrodes of each touch-control area are disposed in the third insulating area and the electrodes are electrically connected to the hub circuit respectively through the plurality of second conductive lines.

15. The capacitive touch-control panel apparatus according to claim 13, wherein a material of the second conductive area and the electrodes is transparent conductive film and a material of the third insulating area is glass or polyethylene.

16. The capacitive touch-control panel apparatus according to claim 14, wherein a material of the second conductive area and the electrodes is transparent conductive film and a material of the third insulating area is glass or polyethylene.

17. The capacitive touch-control panel apparatus according to claim 2, wherein the hub circuit and the touch-control circuit are disposed on the touch-control substrate, and the hub circuit comprises:
a plurality of third conductive lines, electrically connected to the first conductive lines, the plurality of second conductive lines and the touch-control circuit.

18. The capacitive touch-control panel apparatus according to claim 17, wherein each axial body comprises:
a fourth insulating area;
a third conductive area, electrically connected to the hub circuit through one of the first conductive lines, the third conductive area receiving one of the plurality of driving scan signals; and
a fifth insulating area, wherein the electrodes of each touch-control area are disposed in the fifth insulating area, the electrodes are electrically connected to the hub circuit respectively through the plurality of second conductive lines, wherein the fifth insulating area is smaller than the fourth insulating area.

19. The capacitive touch-control panel apparatus according to claim 18, wherein the second conductive lines is disposed on the fifth insulating area and the electrodes and the first conductive area generate mutual capacitance each other.

20. The capacitive touch-control panel apparatus according to claim 19, wherein a material of the third conductive area and the electrodes is transparent conductive film and a material of the fourth insulating area and the fifth insulating area is glass or polyethylene.

21. The capacitive touch-control panel apparatus according to claim 17,
a fourth conductive area, electrically connected to the hub circuit through one of the first conductive lines, the fourth conductive area receiving one of the plurality of driving scan signals; and
a sixth insulating area, wherein the electrodes of each touch-control area are disposed in the sixth insulating area and the electrodes are electrically connected to the hub circuit respectively through the plurality of second conductive lines.

22. The capacitive touch-control panel apparatus according to claim 21, wherein a material of the fourth conductive area and the electrodes is transparent conductive film and a material of the sixth insulating area is glass or polyethylene.

23. The capacitive touch-control panel apparatus according to claim 2, wherein a substrate of the touch-control substrate serves as an outer shell protection layer and the hub circuit is directly embedded on the touch-control substrate.

24. The capacitive touch-control panel apparatus according to claim 23, wherein the touch-control circuit is directly embedded on the touch-control substrate.
